(19) United States
(12) Patent Application Publication
(10) Pub. No.: US 2023/0179129 A1
(43) Pub. Date: Jun. 8, 2023

(54) MOTOR DRIVING DEVICE, MOTOR SYSTEM AND ELECTRICAL DEVICE

(71) Applicant: ROHM CO., LTD., Kyoto (JP)

(72) Inventor: Takashige Miyashita, KYOTO (JP)

(21) Appl. No.: 17/974,733

(22) Filed: Oct. 27, 2022

(30) Foreign Application Priority Data
Dec. 2, 2021 (JP) 2021196283

(51) Int. Cl. H02P 8/12; H02P 8/34

(52) U.S. Cl. CPC H02P 8/12; H02P 8/34

(57) ABSTRACT

The present disclosure provides a motor driving device. The motor driving device includes a generating unit, an adjusting unit, a converting unit and a comparing unit. The generating unit is configured to generate a sensing current corresponding to a motor current that flows through a motor coil. The adjusting unit is configured to give the sensing current a gain corresponding to a limit value of the motor current. The converting unit is configured to perform an I/V conversion on the sensing current with the gain. The comparing unit is configured to compare a reference voltage and an output voltage from the converting unit.

### TECHNICAL FIELD

The present disclosure relates to a motor driving device, a motor system and an electrical device.

### BACKGROUND

FIG. 7 shows a diagram of a configuration example of an H-bridge circuit used in a motor driving device for driving a step motor.

The H-bridge circuit shown in FIG. 7 includes N-channel field-effect transistors (FETs) Q1 and Q3 serving as high-side transistors, and N-channel FETs Q2 and Q4 serving as low-side transistors. An N-channel FET is simply referred to as a transistor where appropriate hereinafter.

A power supply voltage VCC is applied to the drain of each of the transistors Q1 and Q3.

The source and the back gate of the transistor Q1 are connected to the drain of the transistor Q2. The source and the back gate of the transistor Q3 are connected to the drain of the transistor Q4. A ground voltage is applied to the source and the back gate of the transistor Q2 and the source and the back gate of the N-channel FET Q4. The ground voltage is a voltage lower than the power supply voltage VCC.

A motor coil L1 is connected between a connection node N1 and a connection node N2. The connection node N1 is a connection node between the source of the transistor Q1 and the drain of the transistor Q2. The connection node N2 is a connection node between the source of the transistor Q3 and the drain of the transistor Q4.

Moreover, the coil motor L1 is indicated as being one-phase, and two or three motor coils L1 are provided when being two-phase or three-phase. In the present application, only one phase is described for illustration purposes. In the present application, although only one phase is illustrated, similar details apply to driving operation portions of other phases and such repeated details are omitted herein.

The start, switching of a rotation direction and stop of the step motor are controlled by switching a path of a current flowing through the H-bridge circuit. That is to say, a current-feeding mode and a current decay mode are distinguished on the basis of the path of the current flowing through the motor coil L1.

A period after a certain time has elapsed from switching from the current decay mode to the current-feeding mode, that is, a minimum on-time necessarily corresponds to the current-feeding mode. Once the minimum on-time ends, if the current flowing through the motor coil L1 is above a limit value, the current-feeding mode is immediately switched to the current decay mode. On the other hand, if the current flowing through the motor coil L1 when the minimum on-time ends has not yet reached the limit value, the current-feeding mode continues till the current flowing through the motor coil L1 reaches the limit value, and the current-feeding mode is switched to the current decay mode at the time point when the current flowing through the motor coil L1 reaches the limit value.

### PRIOR ART DOCUMENT

### Patent Publication

### Patent Publication 1

Japan Patent Publication No. 2016-208727 (paragraph [0044])

### SUMMARY

### Problems to Be Solved by the Disclosure

A comparator used in a motor driving device compares a voltage corresponding to a current flowing through a motor coil L1 with a reference voltage to determine whether the current flowing through the motor coil L1 has reached a limit value.

Herein, when a set value of the limit value is small, the voltage corresponding to the current supplied to the comparator and flowing through the motor coil L1 and the reference voltage also become small, such that determination precision, that is, current detection precision, of the comparator also degrades.

### Technical Means for Solving the Problem

A motor driving device disclosed by the present application includes: a generating unit, configured to generate a sensing current corresponding to a motor current flowing through a motor coil; an adjusting unit, configured to provide the sensing current a gain corresponding to a limit value of the motor current; a converting unit, configured to perform an I/V conversion on the sensing current with the gain; and a comparing unit, configured to compare a reference voltage and an output voltage of the converting unit.

The motor system disclosed by the present application includes a motor, and the motor driving device configured to drive the motor of the above configuration.

An electrical device disclosed by the present application includes the motor system of the above configuration.

### Effects of the Disclosure

According to the motor driving device, the motor system and the electrical device disclosed by the present application, even when a set value of a limit value of a current flowing through a motor coil is small, high current detection precision can still be achieved.

### BRIEF DESCRIPTION OF THE DRAWINGS

FIG. 1 is a diagram of a brief configuration of a motor system according to an embodiment.

FIG. 2 is a diagram of a configuration example of a current detection unit.

FIG. 3 is a diagram of a configuration example of a resistor with a flat temperature characteristic.

FIG. 4 is a diagram of a distribution example of a resistor with a flat temperature characteristic.

FIG. 5 is a perspective diagram of an appearance of a printer.

FIG. 6 is a diagram of another configuration example of the current detection circuit.

FIG. 7 is a diagram of a configuration example of an H-bridge circuit.

### DETAILED DESCRIPTION OF THE EMBODIMENTS

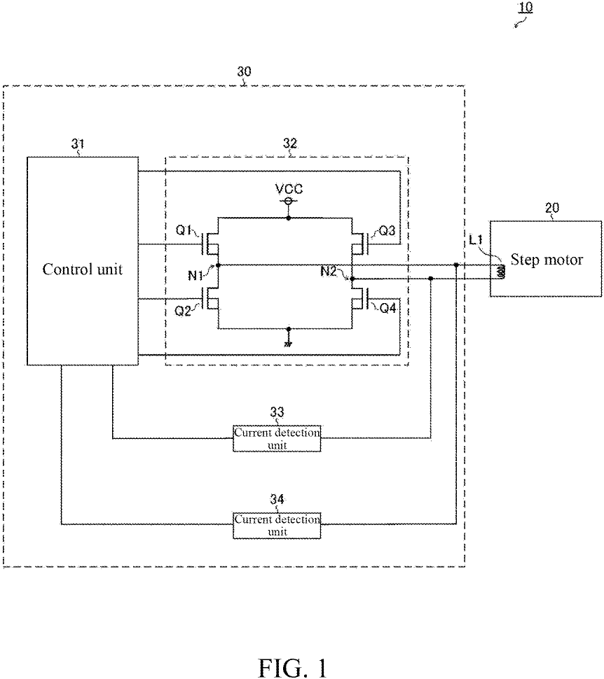

FIG. 1 shows a diagram of a brief configuration of a motor system according to an embodiment. A motor system 10 according to an embodiment includes a step motor 20, and a motor driving device 30 configured to drive the step motor 20.

The motor driving device 30 includes a control unit 31, an H-bridge circuit 32 and current detection units 33 and 34. The H-bridge circuit 32 and the current detection units 33 and 34 correspond to one phase of the step motor 20. When the step motor 20 is two-phase or three-phase, each of the H-bridge circuit 32, and the current detection units 33 and 34 is provided as being two or three in quantity. In the present application, only one phase is shown for illustration purposes. In the present application, although only one phase is illustrated, similar details apply to driving operation portions of other phases and such repeated details are omitted herein. Moreover, one current detection unit may be used in substitution for two current detection units 33 and 34. When one current detection unit is used, one between a voltage from a connection node N1 and a voltage from a connection node N2 is selected using a switching switch and supplied to the current detection unit, and a read timing of the voltage of the connection node N1 and a read timing of the voltage of the connection node N2 are controlled.

The H-bridge circuit 32 is identically configured as the H-bridge circuit in FIG. 7. Moreover, for example, P-channel field-effect transistors (FETs) may also be used in substitution for the N-channel FETs Q1 and Q3.

The control unit 31 performs a current-feeding mode and a current decay mode in each cycle by switching and controlling the individual transistors of the H-bridge circuit 32. The control unit 31 minutely changes a current flowing through the motor coil L 1 by means of microstep control to further rotate a rotor of the step motor 20.

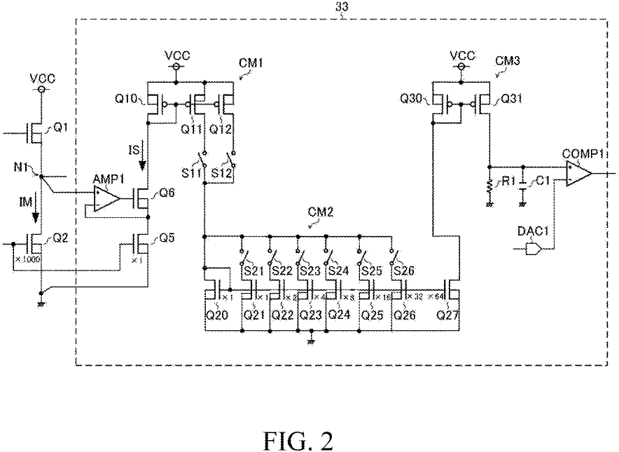

FIG. 2 shows a diagram of a configuration example of the current detection unit 33. The current detection unit 33 includes an N-channel FET Q5, an N-channel FET Q6, an amplifier AMP1, a current source-type current mirror circuit CM1, a current sink-type current mirror circuit CM2, a current source-type current mirror circuit CM3, a resistor R1, a capacitor C1, a digital-to-analog converter (DAC) DAC1, and a comparator COMP1.

The transistor Q5, the transistor Q6 and the amplifier AMP1 are an example of a generating unit, which is configured to generate a sensing current IS corresponding to a motor current IM flowing through the motor coil L1.

The transistor Q5 and the transistor Q2 in a pair form a current mirror circuit. A size ratio of the transistor Q2 to the transistor Q5 is not specifically defined, and is for example, set to be 1000:1. When the size ratio of the transistor Q2 to the transistor Q5 is set to be 1000: 1, the current mirror ratio is 1000:1. By forming a current mirror circuit by the transistor Q2 and the transistor Q5, a ratio of the sensing current IS to the motor current IM can be easily adjusted.

The transistor Q6 is connected in series with the transistor Q5. A non-inverting input terminal of the amplifier AMP1 is connected to the connection node N1, and an inverting input terminal of the amplifier AMP1 is connected to the drain of the transistor Q5 and the source of the transistor Q6. An output terminal of the amplifier AMP1 is connected to the gate of the transistor Q6. The amplifier AMP1 is a buffer amplifier used to render the drain voltage of the transistor Q2 to be equal to the drain voltage of the transistor Q5.

By adjusting an offset voltage of the amplifier AMP1, the level of consistency between the drain voltage of the transistor Q2 and the drain voltage of the transistor Q5 can be improved, even further enhancing the precision of a corresponding relationship between the motor current IM and the sensing current IS.

The current source-type current mirror circuit CM1, the current sink-type current mirror circuit CM2 and the current source-type current mirror circuit CM3 are an example of an adjusting unit, which is configured to provide the sensing current IS a gain corresponding to a limit value of the motor current IM.

The current source-type current mirror circuit CM1 includes P-channel FETs Q10 to Q12, and switches S11 and S12. A P-channel FET is simply referred to as a transistor where appropriate hereinafter.

The drain of the transistor Q10 and the respective gates of the transistors Q10 to Q12 are connected to the drain of the transistor Q6. A power supply voltage VCC is applied to the respective sources and back gates of the transistors Q10 to Q12. The drain of the transistor Q11 is connected to a first terminal of the switch S11. The drain of the transistor Q12 is connected to a first terminal of the switch S12. A second terminal of the switch S11 and the second terminal of the switch S12 are connected to each other.

The current source-type current mirror circuit CM1 is configured to receive the sensing current IS. The control unit 31 (referring to FIG. 1) turns on any one of the switches S11 and S12, and turns off the other switch. Accordingly, a current mirror ratio of the current source-type current mirror circuit CM1 can vary in a two-phase manner.

For example, when the switch S11 is turned on, a maximum value of a range of the motor current IM that can be detected is 2 A; when the switch S12 is turned on, the maximum value of the range of the motor current IM that can be detected is 1 A. Moreover, when the motor current IM is the maximum value of the range that can be detected, the current source-type current mirror circuit CM1 outputs a certain current (for example, a 100 µA current).

The current source-type current mirror circuit CM1 is configured to vary the current mirror ratio, and is hence capable of varying setting of the maximum value of the range of the motor current IM that can be detected. Thus, the motor driving device 30 is capable of dealing with multiple types of step motors 20.

The current sink-type current mirror circuit CM2 includes N-channel FETs Q20 to Q27, and switches S21 to S26.

The drain of the transistor Q20, the respective gates of the transistors Q20 to Q27, and respective first terminals of the switches S21 to S26 are connected to the respective second terminals of the switches S11 and S12. Respective second terminals of the switches S21 to S26 are connected to the drains of the transistors Q21 to Q26, respectively. The respective sources and back gates of the transistors Q20 to Q26 are connected to a ground potential.

The current sink-type current mirror circuit CM2 is configured to receive an output current of the current source-type current mirror circuit CM1. The control unit 31 (referring to FIG. 1) controls turning on and turning off of the switches S21 to S26. The current sink-type current mirror circuit CM2 is configured to vary the current mirror ratio according to a set value of the limit value of the motor current IM. That is to say, the control unit 31 (referring to FIG. 1) controls turning on and turning off of the switches S21 to S26 according to the set value of the limit value of the motor current IM.

A size ratio of the transistors Q20 to Q27 is not specifically defined, and is for example, set to be 1:1:2:4:8:16:32:64. When the size ratio of the transistors Q20 to Q27 is set to be 1:1:2:4:8:16:32:64, if all of the switches S21 to S26 are turned off, the current mirror ratio of the current sink-type current mirror circuit CM2 becomes 1:64. Moreover, when the size ratio of the transistors Q20 to Q27 is set to be 1:1:2:4:8:16:32:64, if the switch S21 is turned off and the switches S22 to S26 are turned on, the current mirror ratio of the current sink-type current mirror circuit CM2 becomes 63:64.

The current sink-type current mirror circuit CM2 is configured to vary the current mirror ratio according to the set value of the limit value of the motor current IM, and hence has an increased number of components. However, due to the current sink-type current mirror circuit, the drain voltage of the transistor Q20 is clamped by a threshold voltage of the transistor Q20. Thus, when the switches S21 to S26 are turned on, a voltage applied to the respective first terminals of the switches S21 to S26, a voltage applied to the respective second terminals of the switches S21 to S26, and the respective drain voltages of the transistors Q21 to Q27 are also clamped by the threshold voltage of the transistor Q20. As such, the transistors Q20 to Q26 and the switches S21 to S26 are free from the concern of being applied with a high voltage, and so the transistors Q20 to Q26 and the switches S21 to S26 can be implemented by components with low withstand voltages. Therefore, low cost and miniaturization of the motor driving device 30 can be achieved.

The current source-type current mirror circuit CM3 includes P-channel FETs Q30 and Q31.

The drain of the transistor Q30 and the respective gates of the transistors Q30 and Q31 are connected to the drain of the transistor Q27. The power supply voltage VCC is applied to the respective sources and back gates of the transistors Q30 and Q31. The drain of the transistor Q31 is connected to a first end of the resistor R1, a first end of the capacitor C1, and the non-inverting input terminal of the comparator COMP1. Moreover, the first end of the resistor Rl and the first end of the capacitor Cl are connected to a ground potential.

The current source-type current mirror circuit CM3 is configured to receive an output current of the current sink-type current mirror circuit CM2.

An output current of the current source-type current mirror circuit CM3 is the sensing current IS having a gain corresponding to the limit value of the motor current IM. That is to say, a value of the output current of the current source-type current mirror circuit CM3 is a value obtained by multiplying the gain corresponding to the limit value of the motor current IM by the sensing current IS.

The resistor R1 is an example of a converting unit, which is configured to perform an I/V conversion on the output current of the current source-type current mirror circuit CM3. The voltage applied to the first end of the resistor R1, that is, the output voltage of the converting unit, passes through the capacitor C1 and becomes smooth.

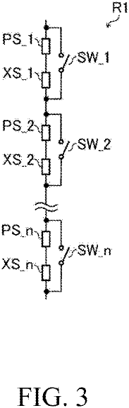

It is desirable that a temperature characteristic of the resistor R1 is flat so that the voltage after the I/V conversion does not have temperature dependence. FIG. 3 shows a diagram of a configuration example of the resistor R1 with a flat temperature characteristic.

The resistor R1 of the configuration example shown in FIG. 3 includes: resistive elements PS_1 to PS_n having a positive temperature characteristic, resistive elements XS_1 to XS_n having a negative temperature characteristic, and switches SW1 to SWn.

Regarding the resistive elements PS_1 to PS_n having a positive temperature characteristic and the resistive elements XS_1 to XS_n having a negative temperature characteristic, both of the resistive elements having a positive temperature and the resistive elements having a negative temperature characteristic are alternately arranged in series connection. The switch SWk (where k is any natural number that is 1 or above and n or below) is connected in parallel to the series connector including the resistive element PS_k having a positive temperature characteristic and the resistive element XS_k having a negative temperature characteristic. By adjusting a ratio of a resistance value of the resistive element PS_k having a positive temperature characteristic to a resistance value of the resistive element XS_k having a negative temperature characteristic, the temperature characteristic of the resistance value of the series connector including the resistive element PS_k having a positive temperature characteristic and the resistive element XS_k having a negative temperature characteristic becomes smooth.

For example, when the switch SW1 is turned on, the resistive element PS_1 having a positive temperature characteristic and the resistive element XS_1 having a negative temperature characteristic are short circuited. Thus, the resistance value of the resistor R1 is adjusted by selecting a switch that is to be turned on from the switches SW1 to SWn.

By adjusting the resistance value of the resistor R1, detection precision can be further enhanced. Regarding the resistor R1 of the configuration example shown in FIG. 3, in each motor driving device 30, the resistance value of the resistor R1 is adjusted by determining a switch that is to be turned on from the switches SW1 to SWn.

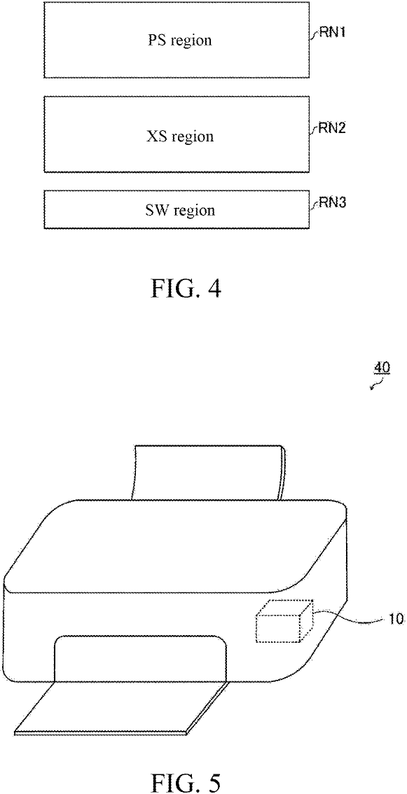

FIG. 4 shows a diagram of a distribution example of the resistor R1 of the configuration example shown in FIG. 3. The resistance elements PS_1 to PS_n having a positive temperature characteristic are disposed in a first region RN1, the resistive elements XS_1 to XS_n having a negative temperature characteristic are disposed in a second region RN2, and the switches SW1 to SWn are disposed in a third region RN3.

The comparator COMP1 is an example of a comparing unit, which is configured to compare the reference voltage and the output voltage of the converting unit. The reference voltage is output from the DAC DAC1. The control unit 31 (referring to FIG. 1) supplies a digital signal that is to become a set value of the reference voltage to the DAC DAC1.

The adjusting unit renders the sensing current IS to have a gain corresponding to the limit value of the motor current IM. Thus, when the set value of the limit value of the motor current IM is small and the motor current IM is the limit value, the output voltage of the converting unit can be inhibited from decreasing. Therefore, even when the set value of the limit value of the motor current IM is small, high current detection precision can still be achieved.

Moreover, preferably, the output voltage of the converting unit is kept constant when the motor current IM is the limit value, regardless of the set value of the limit value of the motor current IM. Thus, the setting of the reference voltage used for microstep control is kept constant regardless of a set value of the limit value of the motor current IM, such that microstep control becomes easy.

The motor system 10 of the embodiment is, for example, built in a printer 40 shown in FIG. 5, as a part of a paper conveying mechanism. Moreover, the motor system 10 of the embodiment may also be equipped in an electrical device other than a printer.

In addition to the embodiments, various modifications may be made to the configurations of the present disclosure without departing from the scope of the inventive subject thereof. It should be considered that all aspects of the embodiment are illustrative rather than restrictive, and it should be understood that the technical scope of the present disclosure is represented by way of the claims but not the descriptions of the embodiments, including all meanings equivalent to the claims and variations made within the scope of the present disclosure.

For example, bipolar transistors may also be used in substitution for FETs.

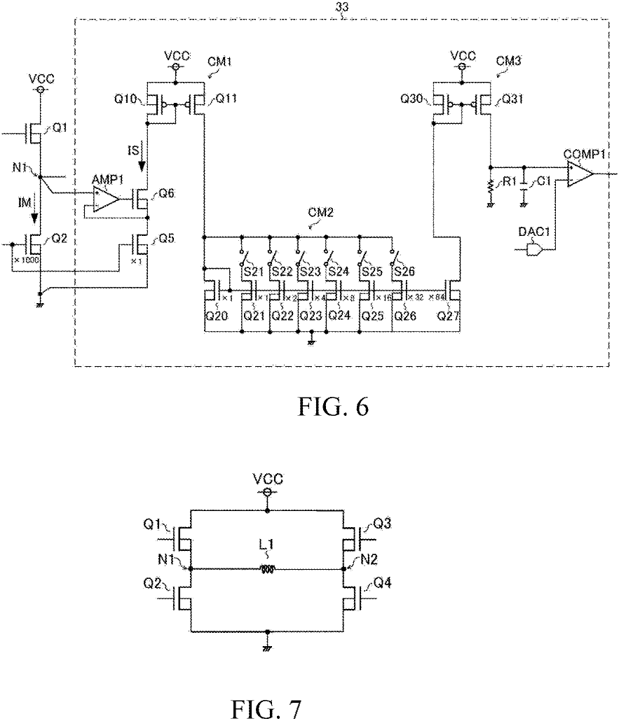

For example, when the setting of the maximum value of the range of the motor current IM that can be detected does not need to be changed, the current detection unit 33 is set to the configuration in FIG. 6. In the current detection unit 33 as the configuration in FIG. 6, the current mirror ratio of the current source-type current mirror circuit CM1 is constant.

The motor driving device (30) described above is configured (a first configuration) to include: a generating unit (Q5, Q6, AMP1), configured to generate a sensing current corresponding to a motor current flowing through a motor coil (L1); an adjusting unit (CM1, CM2, CM3), configured to provide the sensing current a gain corresponding to a limit value of the motor current; a converting unit (R1), configured to perform an I/V conversion on the sensing current with the gain; and a comparing unit (COMP1), configured to compare a reference voltage and an output voltage of the converting unit.

In the motor driving device of the first configuration, the adjusting unit renders the sensing current to have a gain corresponding to a limit value of the motor current. Thus, when a set value of the limit value of the motor current is small and the motor current is the limit value, an output voltage of the converting unit can be inhibited from decreasing. Therefore, even when the set value of the limit value of the motor current is small, high current detection precision can still be achieved.

The motor driving device of the first configuration may also be configured (a second configuration) as, wherein the motor coil is configured to be connectable to a second end of a first transistor (Q1) and a first end of a second transistor (Q2), wherein the first transistor (Q1) includes a first end connectable to an application end of a power supply voltage, and the second transistor (Q2) includes a second end connectable to an application end of a voltage less than the power supply voltage, and the generating unit includes a third transistor (Q5) paired with the second transistor to form a current mirror circuit.

In the motor driving device of the second configuration, a current mirror circuit is formed by the second transistor and the third transistor, and thus a ratio of the sensing current to the motor current can be easily adjusted.

The motor driving device of the second configuration may also be configured (a third configuration) as, wherein the generating unit includes: a fourth transistor (Q6), configured to be connectable in series with the third transistor; and an amplifier (AMP1), configured to control the fourth transistor according to a voltage applied to a connection node between the third transistor and the fourth transistor, and a voltage applied to a first end of the second transistor.

In the motor driving device of the third configuration, by adjusting an offset voltage of the amplifier, precision of a corresponding relationship between the motor current and the sensing current can be enhanced.

The motor driving device of any one of the first to third configurations may also be configured (a fourth configuration) as, wherein the adjusting unit includes: a current source-type current mirror circuit (CM1), configured to receive the sensing current; and a current sink-type current mirror circuit (CM2), configured to receive an output current of the current source-type current mirror circuit, and wherein the current sink-type current mirror circuit is configured to vary a current mirror ratio according to a set value of the limit value.

In the motor driving device of the fourth configuration, the current sink-type current mirror circuit is configured to be capable of varying a current mirror ratio according to the set value of the limit value of the motor current, and thus the number of components is increased. However, due to the current sink type, components with low withstand voltages can be used. Therefore, low cost and miniaturization can be achieved.

The motor driving device of the fourth configuration may also be configured (a fifth configuration) as, wherein the current source-type current mirror circuit is configured to vary the current mirror ratio.

In the motor driving device of the fifth configuration, setting of a maximum value of a range of a motor current that can be detected can be varied, and thus various types of step motors can be dealt with.

The motor driving device of any one of the first to fifth configurations may also be configured (a sixth configuration) as, wherein the output voltage of the converting unit is constant when the motor current is the limit value regardless of a set value of the limit value.

In the motor driving device of the sixth configuration, setting of a reference voltage used for microstep control is kept constant regardless of a set value of the limit value of the motor current.

The motor system (10) of the description above is configured (a seventh configuration) to include: a motor (20), and the motor driving device of any one of the first to sixth configurations configured to drive the motor.

In the motor system of the seventh configuration, even when a set value of a limit value of a current flowing through a motor coil is small, high current detection precision can still be achieved.

The electrical device (40) of the description above is configured (an eighth configuration) to include the motor system of the seventh configuration.

In the electrical device of the eighth configuration, even when a set value of a limit value of a current flowing through a motor coil is small, high current detection precision can still be achieved.

1. A motor driving device, comprising:
a generating unit, configured to generate a sensing current corresponding to a motor current flowing through a motor coil;
an adjusting unit, configured to provide the sensing current a gain corresponding to a limit value of the motor current;
a converting unit, configured to perform an I/V conversion on the sensing current with the gain; and
a comparing unit, configured to compare a reference voltage and an output voltage of the converting unit.

2. The motor driving device of claim 1, wherein
the motor coil is configured to be connectable to
a second end of a first transistor, wherein the first transistor includes a first end connectable to an application end of a power supply voltage; and
a first end of a second transistor, wherein the second transistor includes a second end connectable to an application end of a voltage less than the power supply voltage, and
the generating unit includes a third transistor paired with the second transistor to form a current mirror circuit.

3. The motor driving device of claim 2, wherein the generating unit includes:
a fourth transistor, configured to be connectable in series with the third transistor; and
an amplifier, configured to control the fourth transistor according to a voltage applied to a connection node between the third transistor and the fourth transistor, and a voltage applied to a first end of the second transistor.

4. The motor driving device of claim 1, wherein
the adjusting unit includes:
a current source-type current mirror circuit, configured to receive the sensing current; and
a current sink-type current mirror circuit, configured to receive an output current of the current source-type current mirror circuit, and
the current sink-type current mirror circuit is configured to vary a current mirror ratio according to a set value of the limit value.

5. The motor driving device of claim 2, wherein
the adjusting unit includes:
a current source-type current mirror circuit, configured to receive the sensing current; and
a current sink-type current mirror circuit, configured to receive an output current of the current source-type current mirror circuit, and
the current sink-type current mirror circuit is configured to vary a current mirror ratio according to a set value of the limit value.

6. The motor driving device of claim 3, wherein
the adjusting unit includes:
a current source-type current mirror circuit, configured to receive the sensing current; and
a current sink-type current mirror circuit, configured to receive an output current of the current source-type current mirror circuit, and
the current sink-type current mirror circuit is configured to vary a current mirror ratio according to a set value of the limit value.

7. The motor driving device of claim 4, wherein the current source-type current mirror circuit is configured to vary the current mirror ratio.

8. The motor driving device of claim 5, wherein the current source-type current mirror circuit is configured to vary the current mirror ratio.

9. The motor driving device of claim 6, wherein the current source-type current mirror circuit is configured to vary the current mirror ratio.

10. The motor driving device of claim 1, wherein the output voltage of the converting unit is constant when the motor current is the limit value regardless of a set value of the limit value.

11. The motor driving device of claim 2, wherein the output voltage of the converting unit is constant when the motor current is the limit value regardless of a set value of the limit value.

12. The motor driving device of claim 3, wherein the output voltage of the converting unit is constant when the motor current is the limit value regardless of a set value of the limit value.

13. The motor driving device of claim 4, wherein the output voltage of the converting unit is constant when the motor current is the limit value regardless of a set value of the limit value.

14. The motor driving device of claim 7, wherein the output voltage of the converting unit is constant when the motor current is the limit value regardless of a set value of the limit value.

15. A motor system, comprising:
a motor; and
a motor driving device of claim 1, configured to drive the motor.

16. A motor system, comprising:
a motor; and
a motor driving device of claim 2, configured to drive the motor.

17. A motor system, comprising:
a motor; and
a motor driving device of claim 3, configured to drive the motor.

18. An electrical device, comprising the motor system of claim 15.

19. An electrical device, comprising the motor system of claim 16.

20. An electrical device, comprising the motor system of claim 17.
